(19) United States
(12) Patent Application Publication
(10) Pub. No.: US 2019/0072519 A1
(43) Pub. Date: Mar. 7, 2019

(54) Electrostatic Force Detector With Improved Shielding And Method Of Using An Electrostatic Force Detector

(71) Applicant: Trek, Inc., Lockport, NY (US)

(72) Inventors: Toshio Uehara, Tokyo (JP); Jumpei Higashio, Tokyo (JP)

(21) Appl. No.: 16/070,743

(22) PCT Filed: Apr. 10, 2017
(86) PCT No.: PCT/US2017/026846

§ 371 Date: Jul. 17, 2018

Related U.S. Application Data
(60) Provisional application No. 62/320,409, filed on Apr. 8, 2016.

(51) Int. Cl. G01N 27/60; G01R 29/12; G01R 29/24; G01R 29/08

(52) U.S. Cl. CPC G01N 27/60; G01R 29/0885; G01R 29/24; G01R 29/12

(57) ABSTRACT

An electrostatic force detector (“EFD”) for measuring electrostatic force of a surface under test (“SUT”) includes a force detector comprising a cantilevered arm and a probe. The EFD has a shield with a hole through which the probe extends and is positioned to prevent electromagnetic energy from the SUT from reaching the cantilevered arm and most of the probe, and preventing light from reaching the SUT. A method for selecting a voltage range for an EFD measuring a charge on an SUT includes measuring with the EFD two voltages at or near the end-points of an estimated voltage-range, and then comparing the polarities. If the polarities differ, the estimated voltage-range is selected. However, if the polarities are the same, then the estimated voltage range is adjusted to provide a new estimated voltage-range, which is then tested for purposes of determining whether the charge on the SUT is within the range.

### CROSS-REFERENCE TO RELATED APPLICATION

This application claims the benefit of priority to U.S. provisional patent application Ser. No. 62/320,409, filed on Apr. 8, 2016.

### FIELD OF THE INVENTION

The present invention relates to devices, systems, and methods of measuring electrostatic charge on a surface under test (“SUT”). Such SUTs may include, among others, electrophotography drums in copiers, and microscopy.

### BACKGROUND OF THE INVENTION

An electrostatic force detector (“EFD”) may be used to measure electrostatic charge on an SUT. An EFD may be used in high-precision measuring instruments, such as atomic force microscopes (“AFM”), electrostatic force microscopes (“EFM”), and similar critical-dimension measurement instruments. In an EFD, a probe part extends from a cantilevered arm toward the SUT. The probe part is often shaped to be much longer than it is wide, and may taper to a tip having a very small surface area. The tip of the probe part is positioned close to the SUT. Ideally, electrostatic forces exerted on the EFD by charges on the SUT are exerted only on the tip of the probe part, but prior art devices do not achieve such an ideal state. Measurement errors are created in prior art devices when electrostatic forces are exerted at locations other than the tip, for example on the cantilevered arm or the shaft of the probe part between the cantilevered arm and the tip. Consequently, the prior art devices do not accurately measure the charge on an SUT.

Some prior art devices shield portions of the force detector in order to reduce electrostatic forces that would otherwise be exerted on the cantilevered arm, so that the accuracy of the measurement is improved. In those prior art devices a shield is positioned between the SUT and the cantilevered arm. Although such prior art shields substantially shield the cantilevered arm from the effects of the electrostatic charges residing on the SUT, the prior art shields do not properly shield the shaft of the probe part from the effects of the electrostatic charges on the SUT. Errors are realized by the prior art devices because (in addition to the tip) the shaft of the probe part is subjected to electrostatic forces caused by the electrostatic charges residing on the SUT.

In addition, many SUTs are photosensitive. The arrangement of prior art shields fails to adequately reduce unwanted light from reaching the SUT. Since the photosensitivity of many SUTs having a photoreceptor is around 0.15 to 0.4 μJ/cm², a small amount of light reaching the SUT can make a measurable difference in the charge on the SUT. Regardless of the source, if unwanted light reaches an SUT that is photosensitive, the unwanted light changes the charge residing on the SUT and thereby makes it impossible to obtain an accurate measurement of the charge that was supposed to be on the SUT. This is the case even when the light intensity is extremely low.

### SUMMARY OF THE INVENTION

The invention may be embodied as an electrostatic force detector (“EFD”) for measuring electrostatic force of a surface under test (“SUT”). The EFD may include:
(a) a force detector having a cantilevered arm and a probe, the probe extending from the cantilevered arm at a location that is distal from a fulcrum of the cantilevered arm and oriented so that electrostatic force due to electrostatic charge on the SUT is induced at a tip of the probe;
(b) an optical system for transforming bending of the cantilevered arm due to electrostatic force induced at the tip into an electrical signal containing a frequency component of the electrostatic force induced at the tip;
(c) a voltage source for applying bias voltage to the force detector;
(d) a frequency detector for detecting the frequency component of the electrical signal so that a measurement of electrostatic charge on the SUT can be obtained; and
(e) a shield having a surface defining a hole through the shield, the shield being positioned to inhibit electromagnetic energy from the SUT from reaching the cantilevered arm and to prevent light from reaching the SUT, wherein the shield is located between the cantilevered arm and the SUT, and a portion of the probe extends through the hole in the shield.

The shield:
(1) may be located closer to the SUT than to the cantilevered arm; and/or
(2) maintained at the same electrical potential as the force detector so that lines of electrostatic force are terminated at the shield; and/or
(3) may have a width equal to or greater than the width of the cantilevered arm.

The cantilevered arm may:
(1) have a length between 900 μm and 3600 μm; and/or
(2) have a width between 400 μm and 1400 μm.

The invention may be embodied as a method in which a voltage range for an EFD is selected. Such a method may include:
(a) providing a first estimate of a voltage (“first voltage estimate”) of a charge residing on a surface under test (“SUT”);
(b) selecting a voltage range that includes the first voltage estimate, the voltage range extending from a first voltage (“Vdc-high”) to a second voltage (“Vdc-low”);
(c) positioning a probe tip of the EFD at a distance from the SUT that will avoid arcing between the probe tip and the SUT;
(d) using Vdc-high, applying an input voltage to the probe tip according to the following equation:

Vₜ=V_{AC} Sin ωt+V_{DC}
and obtaining a first voltage-indication of a measured output voltage from the EFD;
(e) using Vdc-low, applying an input voltage to the probe tip according to the following equation:

Vₜ=V_{AC} Sin ωt+V_{DC}
and obtaining a second voltage-indication of the measured output voltage from the EFD;
(f) comparing a polarity of the first voltage-indication to a polarity of the second voltage-indication to provide a first polarity-indication;
(g) if the first polarity-indication indicates opposite polarities, then concluding that the charge is within the selected voltage range;
(h) if the first polarity-indication indicates same polarities, then concluding that the charge is not within the selected voltage range.
   If it is concluded that the charge is within the selected voltage range, then the charge on the SUT may be measured using the EFD. However, if it is concluded that the charge is not within the selected voltage range, then a new voltage estimate may be provided, and steps “b” through “h” may be repeated using the new voltage estimate in lieu of the first voltage estimate. Once it is determined that the charge is within the selected voltage range, either the probe may be moved closer to the SUT or the determined charge may be provided as the measurement of the charge residing on the SUT at that particular location. Such a method may be useful in precisely determining the charge on the SUT by keeping the measurement range narrow, while also preventing arcing by keeping the probe at a safe distance until some idea of the charge is obtained.

If the polarities are determined to be the same (either both are +, or both are −), then the estimated range may be modified. To do so, a determination may be made regarding whether the first voltage-indication has a polarity less than zero, and if so, then the new voltage estimate may be selected to be the first voltage estimate minus a selected difference-number. But, if the first voltage-indication has a polarity that is greater than zero, then the new voltage estimate is selected to be the first voltage estimate plus a selected difference-number. For example, the selected difference-number may be a multiple of 40 volts.

### BRIEF DESCRIPTION OF THE DRAWINGS

For a fuller understanding of the nature and objects of the invention, reference should be made to the accompanying drawings and the subsequent description. Briefly, the drawings are:

FIG. 1a is a schematic diagram of a prior art EFM without a shield;

FIG. 1b is a schematic perspective view illustrating a systematic head of a prior art EFM without a shield;

FIG. 2 is a diagrammatic view of a parallel plane model of a prior art EFM;

FIG. 3 is a diagrammatic view illustrating a portion of a prior art EFM;

FIGS. 4A, 4B, and 4C are perspective diagrams illustrating aspects of an EFD according to the present invention;

FIG. 5 is a schematic diagram of an EFD with a shield according to the invention;

FIG. 6 is a graph that shows the reduction in light reaching the SUT that may be achieved by using our shield;

FIG. 7 is a graph that plots a voltage difference versus Vω);

FIG. 8 is a flowchart for a method according to our invention for which a target voltage input range may be determined;

FIG. 9 is a graph illustrating the change in surface voltage of an SUT with time;

FIG. 10 shows test results for a latent image measurement (Low mobility);

FIG. 11 shows test results for a latent image measurement (High mobility); and

FIG. 12 is a graph that plots exposure energy vs. latent image voltage.

### FURTHER DESCRIPTION OF THE INVENTION

The present invention is an EFD, such as an EFM, for measuring electric charge on an SUT. The invention may be used in devices other than an EFM, and the invention is therefore not limited to an EFM. The invention may be used with an SUT that is an electrophotography drum in a photocopier, or for piezoceramic manufacturing. So, even though the description sometimes focuses on EFM's, claims in this document are not necessarily limited to an EFM, unless such a claim expressly calls out an EFM.

The invention may be embodied as an EFD that includes a force detector. The force detector may be comprised of a cantilevered arm and a probe extending from the cantilevered arm. The force detector may be formed from a single piece of material. The probe may be comprised of a shaft that terminates in a tip, and the tip ideally has a small surface area. In use, the tip of the probe is positioned close to the SUT so that charges on the SUT induce an electrostatic force at the tip. The force exerted on the tip is transmitted via the shaft of the probe to the cantilevered arm so that the cantilevered arm is caused to bend. A laser may be pointed at a reflective surface of the cantilevered arm. Laser light from the laser is reflected from the cantilevered arm and received at a photo detector. The location of the received laser light is indicative of the curvature of the cantilevered arm, and the curvature is indicative of the force being exerted on the cantilevered arm. Thus, by detecting the location of the reflected laser light on the photo detector, it is possible to determine the force being exerted on the cantilevered arm. For example, a detection circuit may be designed and/or calibrated to correlate a particular location on the photo detector with a particular amount of charge on the SUT.

Since the curvature of the cantilevered arm is used to determine the amount of charge on the SUT, and since the curvature is caused by forces exerted on the probe, it is beneficial to limit such forces to those forces that are exerted on the tip as a result of charges on the SUT. To improve measurement accuracy, one or more shields may be employed in order to prevent electrostatic charges on the SUT from exerting forces on the force detector at locations other than the probe tip, such as on the cantilevered arm and/or the shaft of the probe near the cantilevered arm.

Furthermore, light that is received by the SUT could affect the charge on the SUT, particularly when the SUT is photosensitive. Such light may originate from the laser, or elsewhere. For example, such SUT-received light may result from (a) imperfect reflection of the laser light off of the cantilevered arm, (b) imperfect transmission of the laser light through the ambient medium, which may be caused by contaminates in the ambient gas, and/or (c) less than full absorption of light received at the photo detector. To reduce the amount of SUT-received light, embodiments of our invention may employ one or more shields, one or more of which may be placed between the cantilevered arm and the SUT, and also may extend beyond the probe. When an embodiment of our invention has a shield that extends beyond the probe, an orifice may be provided in the shield in order to allow the probe to extend through the shield. Furthermore, one or more of the shields may be wider than the cantilevered arm.

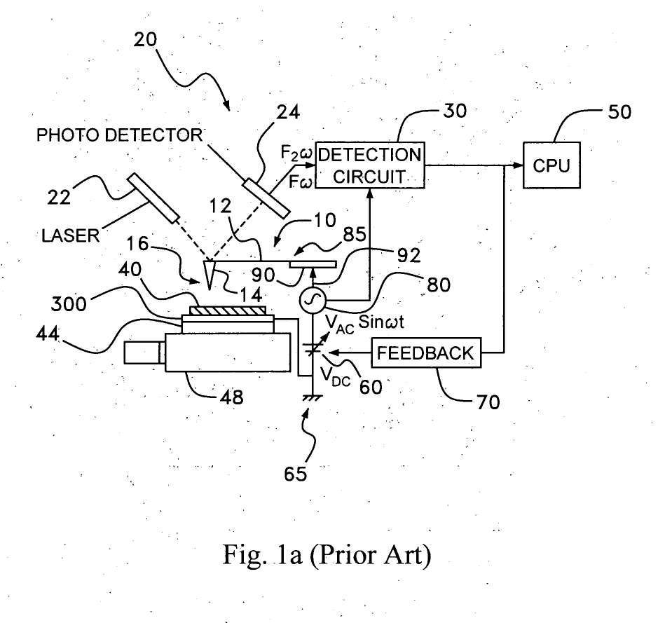

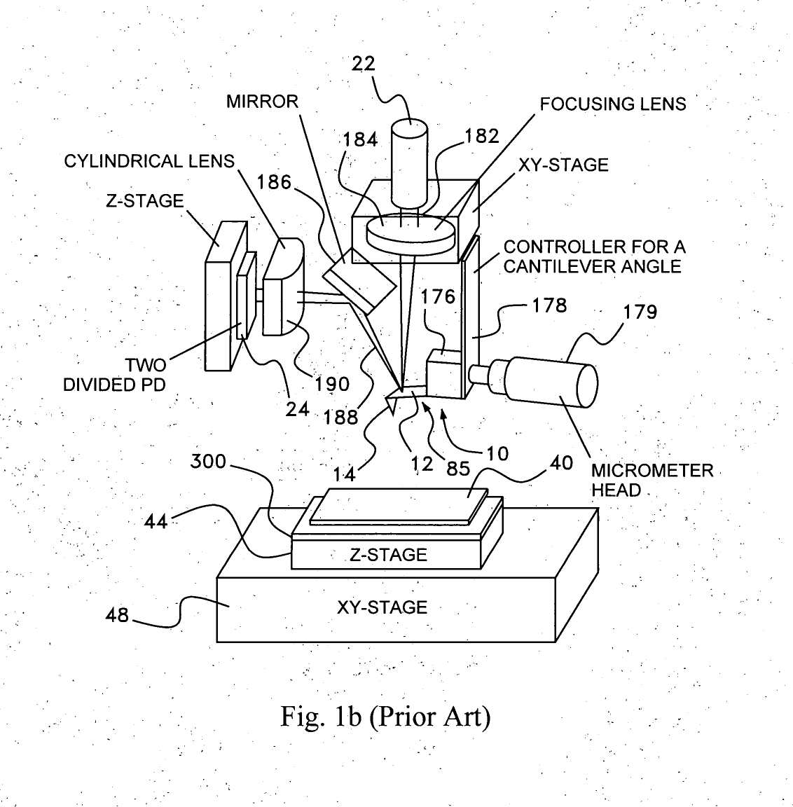

A representative configuration of a prior art electrostatic force microscope to which the present invention may be applied is shown is FIG. 1a and FIG. 1b. The prior art system has an optical system 20 and a force detector, which is generally designated 10. The force detector has a cantilevered arm 12 and a probe 14 having a tip 16. The optical system 20 may have a laser 22, a photodetector 24, and a detection circuit 30. An SUT 40 may be operatively associated with an actuator 44, such as a piezoelectric driver which, in turn, is operatively associated with a scanner 48. A processor 50 may be in communication with the output of the detection circuit 30, and used to process data obtained from the detection circuit 30. A feedback circuit 70 has an input electrically connected to the output of the detection circuit 30, and an output electrically connected in controlling relation to a DC source 60. Both the SUT 40 and the DC source 60 may be electrically connected to an electrical ground or reference 65. The combination of DC source 60 and AC source 80 is connected to force detector 10 and to detection circuit 30.

Electrostatic force is induced at the tip 16 of the detector 10 due to a charge on the SUT 40. The electrostatic force on the tip 16 causes the cantilevered arm 12 to bend from a fulcrum 85 because one end of the cantilevered arm 12 is fixed, in this case to a transducer 90. The transducer 90 may be a piezoelectric device that creates motion on the arm 12 corresponding to an electric signal provided to the transducer 90.

The amount that the cantilevered arm bends is transduced to an electrical signal by using the optical-lever method. An external bias voltage, which has a DC and an AC component, is applied via conductor 92 to the transducer 90 in order to distinguish the polarity of the charge on the SUT 40. The bias voltage Vt is given by the equation:

Vₜ=V_{AC} Sin ωt+V_{DC} Eq. 1

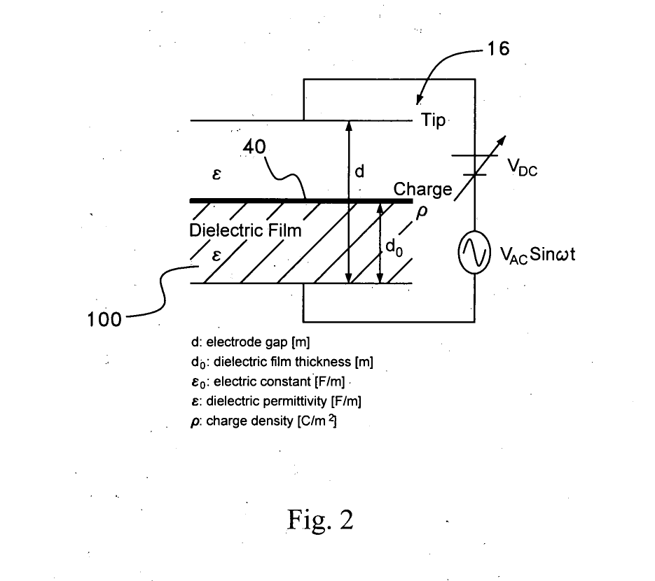

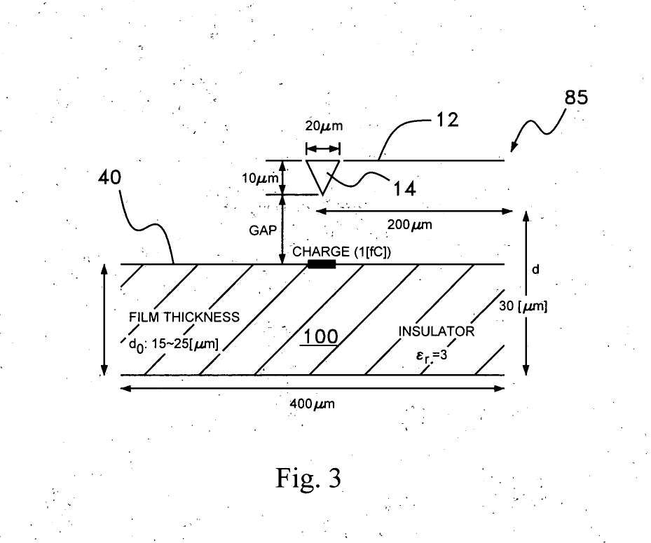

The photo detector 24 receives reflected laser light, which has been modulated by the electric signal applied to the transducer 90, and provides the detector 30 with a signal which contains the frequency components of ω and 2ω. If the relation between the tip 16 and the SUT 40 is considered as a parallel plane model (see FIG. 2 and FIG. 3), the following equations give information corresponding to each of ω and 2ω from the electrostatic force induced on the probe tip 16.

$$\begin{matrix}{F}_{ω} = \frac{{V}_{DC} - ρ {d}_{0} \text{/} ɛ}{{[ d - ( 1 - {ɛ}_{0} \text{/} ɛ ) {d}_{0} ]}^{2}} {ɛ}_{0} {SV}_{AC} sin ω t & Eq . 2 \\ {F}_{2 ω} = \frac{- 1}{{4 [ d - ( 1 - {ɛ}_{0} \text{/} ɛ ) {d}_{0} ]}^{2}} {ɛ}_{0} {SV}_{AC}^{2} cos 2 ω t & Eq . 3\end{matrix}$$

In the foregoing equations, Vt is the external bias voltage, ρ is the density of the charge distribution on the SUT 40, ε is the dielectric constant of the SUT 40, dₒ is the thickness of the SUT 40, d is the distance between the probe tip 16 and the metal substrate 300 and S is the area of the SUT 40 that is being sensed by the tip 16. If ε and dₒ are known, it is possible to calculate p (the density of the charge distribution) by detecting F_{ω} (ω component of electrostatic force), or by measuring V_{DC}, which is given to the detector as a feedback to let F_{ω} become zero. If dₒ is zero, it means that the surface under test is a solid metal, and the probe is no longer positioned over the SUT 40. Since one has to measure the charge distribution on the dielectric film 100, the condition of dₒ=0 is not realistic, therefore one has to measure F_{2ω} directly.

In order to be able to calculate the density of the charge distribution on the SUT 40 for a particular location (i.e. the charge on the SUT 40), the electrostatic force that is induced between the probe tip 16 and surface charge on the SUT 40 must be determined. To obtain the voltage distribution, Poisson's equation may be useful:

∇²V=−ρ/∈ₒ Eq. 4

where V is the voltage to be obtained from this calculation, p is the density of the charge distribution, and εₒ is the dielectric constant of vacuum.

The electrostatic field distribution of the area being sensed by the probe tip 16 may be determined by utilizing the above mentioned voltage distribution (∇²V). One calculates the electrostatic force which is induced between the tip 16 and the charge on the SUT 40 from data obtained through the previous two steps.

FIG. 1b further illustrates aspects of the prior art EFM depicted in FIG. 1a. Force detector 10 has a probe 14 fixed at one end of the cantilevered arm 12, and the other end of arm 12 is fixed to a body 176 that is operatively associated with a controller 178 for the cantilever angle and a micrometer head 179. A laser 22 provides a beam 182 which is focused by lens 184 onto cantilevered arm 12. A mirror 186 directs the reflected beam 188 to a cylindrical lens 190 which concentrates the beam onto a photodetector 24. FIG. 1b depicts the SUT 40 on a piezo-actuator 44 that is operatively associated with an X-Y stage 48 and serves to position the SUT 40 with respect to the probe tip 16. The X-Y stage 48 allows the SUT 40 to be moved without changing the distance between the SUT 40 and the probe 14. The piezo-actuator 44 moves the SUT 40 closer or farther from the probe tip 16.

With reference to Eq. 3, F_{2ω} can be used to provide information about roughness of the SUT 40. It may be useful to provide some detail regarding how this can be accomplished. With reference to FIG. 1a, the detection circuit 30, CPU 50, and feedback circuit 70 work in conjunction with the piezo-actuator 44 and X-Y stage 48 to (a) move the SUT 40 in the x-axis and/or y-axis in order to position a particular location of the SUT 40 under the tip 16, (b) using Eq. 3, F_{2ω} is determined for that x-y location, (c) the position of the SUT 40 in the z-axis is adjusted using the piezo-actuator 44 to make F_{2ω} equal to a predetermined constant value, (d) by knowing the position of the SUT 40 in the z-axis, d can be determined, and (e) by knowing d, the corresponding charge on the SUT 40 at that x-y position can be determined from a look up table, or other means.

The electrostatic force detector with cantilevered arm described above has been designed and manufactured so that electrostatic charge on a dielectric film, which is located on a conductive surface, can be detected. With the method and apparatus as described, scanning in a relatively large area (e.g. several hundred square millimeters) may be provided with relatively high spatial resolution and a precise measurement of charge distribution. To achieve such a precise measurement, it is necessary to measure the thickness of the dielectric film that holds the charge.

It has been ascertained that systems and methods of determining the electrostatic charge on a film having a thickness dₒ via the effects of an electrostatic force are susceptible to errors that arise from a change in the electrostatic force that results from a change of the film thickness dₒ because the equivalent tip area which “sees” the SUT 40 changes due to the change of dₒ. Thus, in order to determine a more accurate measurement about the amount of electrostatic charge on the SUT 40, one must adjust the data that is gathered by the EFD using information about changes in the dielectric film thickness. A film thickness measurement method is proposed herein which utilizes a detected F_{2ω} component arising from the AC bias voltage. By adjusting the measured force data to take film thickness into account, the error that would otherwise be present can be reduced to less than 10%, and most of that error can be attributed to the change of film thickness dₒ.

A probe 14 that is in keeping with the invention may be made to detect electrostatic charge with less than 1 fC sensitivity and a spatial resolution of 10 μm. Such a probe 14 may be made from nickel foil. With such a probe 14, the invention may be used to measure both electrostatic charge on the SUT 40 and film thickness of the SUT 40 simultaneously so that one can then adjust the measured electrostatic charge, and thereby determine the actual amount of electrostatic charge on the SUT 40.

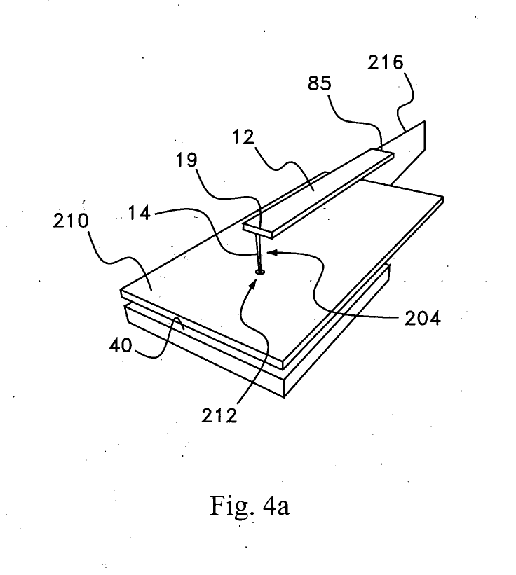

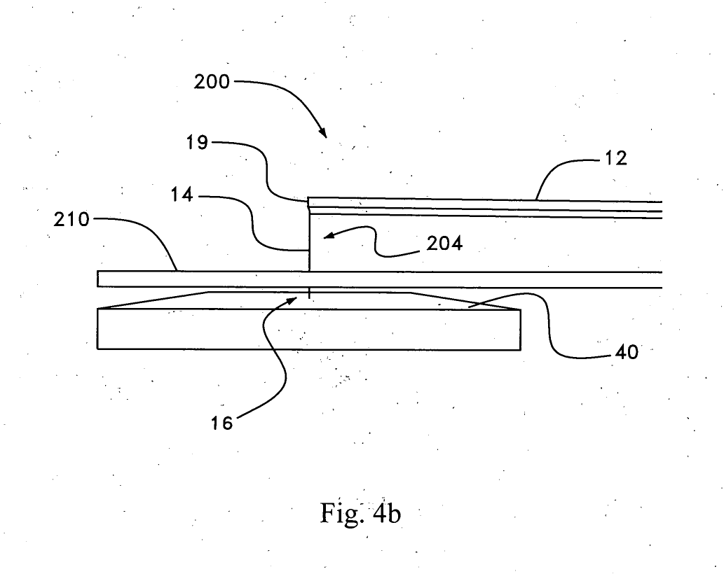

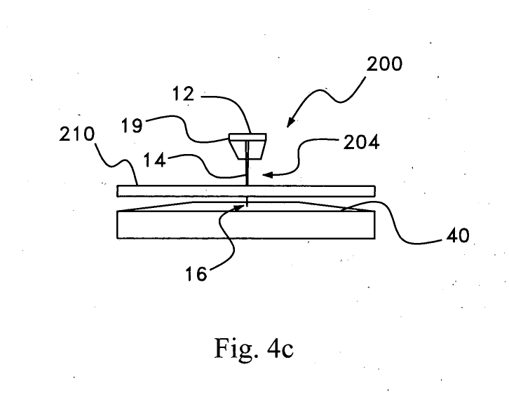

When an electrostatic force is applied to the tip 16 of the probe 14, additional electrostatic force caused by the same electrostatic field may appear at the cantilevered arm 12, which can cause a measurement error and reduce the spatial resolution of the probe. In accordance with the present invention, the cantilevered arm 12 and a large portion of the shaft 204 of the probe 14 are shielded from the SUT 40 in order to prevent the charges on the SUT 40 from acting on the shielded sections of the probe 14 so that the accuracy of the measurement system is improved. Referring to FIG. 4A, FIG. 4B, and FIG. 4C, there is shown a force detector 200 of an EFD that is in keeping with the invention. Force detector 200 includes a cantilevered arm 12 and a probe 14 with a tip 16. The probe 14 can have various shapes and sizes. In FIGS. 4A, 4B, and 4C the probe 14 is depicted as having a shaft 204 that has a length greater than that of prior art shafts. A shaft 204 of the present invention may be between 200 μm and 1000 μm in length. In accordance with the present invention, an electrostatic shield 210 is operatively associated with cantilevered arm 12 of force detector 200. Shield 210 may be a conductive material, such as metal, and is shown in the figures as an elongated strip located between cantilevered arm 202 and the SUT 40. The shield 210 is closely spaced to the SUT 40, preferably less than 300 μm. The length of shield 210 preferably is longer than the cantilevered arm 12 so that a distal end 19 of the cantilevered arm 12 is shielded from electrostatic charges on the SUT 40. By assuring that the distal end 19 is shielded, a substantial portion of the shaft 204 will also be shielded from electrostatic charges residing on the SUT 40. In the arrangement illustrated in FIG. 4A, FIG. 4B, and FIG. 4C, the width of shield 210 is substantially greater than the width of cantilevered arm 12. Although the shield 210 can have other widths, the shield 210 is at least greater than the width of cantilevered arm 12. It is believed that for many embodiments of the invention, adequate shielding may be achieved if the shield 210 is about 5 mm longer and 8 mm wider than the cantilevered arm 12.

The force detector 200 and shield 210 may be maintained at the same or nearly the same electrical potential. This is represented diagrammatically in FIG. 4A by a conductive connection 216, but the desired result may be achieved by using a voltage source, which provides the same voltage to both arm 12 and shield 210. Other arrangements may be employed to keep the cantilevered arm 12 and shield 210 at the same electrical potential, including providing a conductor between them. By maintaining the voltage of both the arm 12 and shield 210 the same, the electric force created by charges on the SUT 40 at locations other than where the tip 16 is situated are not applied to the cantilevered arm 12 or shielded portions of the probe 14, but instead are applied to the shield 210. As a result, the force applied to the detector 200 is limited to that force which is associated with the charge located at a specific portion of the SUT 40 and is applied primarily to that portion of the probe 14 that resides between the shield 210 and the SUT 40, and therefore largely at the tip 16 of the probe 14. When compared to prior art devices, our shield arrangement allows a greater percentage of the electrostatic force applied to the force detector 200 to come from the tip 16. It is believed that our arrangement is capable of nearly eliminating forces arising from charges other than the charge that is nearest to the tip 16.

Having provided an overview of an EFD that is in keeping with the present invention, additional detail about the invention will be provided below.

In some situations, such as electrophotography, the charges on the SUT 40 that need to be measured are quite high, e.g. +/−1 kV. Furthermore, the SUT 40 is quite large relative to the resolution required, and thus many measurement readings are required in order to provide useful information about the SUT 40. For example, in many situations, the total area to be analyzed is about several hundred square millimeters, and the required spatial resolution is on the order of 10 micrometers. Although a conventional Kelvin Force Microscope (“KFM”) has the capability to measure surface voltage with a spatial resolution of 10 nm to 100 nm, the area over which a KFM can realistically measure is in the range of a few hundred square micrometers, which is very small compared to what is expected of electrophotography. By way of contrast, prior art electrostatic voltmeters that employ capacitive coupling between the sensor and the SUT 40 have the ability to scan a wide area (e.g. 200 mm²), but the spatial resolution is normally only as low as a few millimeters. Ideally, an improved EFD would have the ability to scan a much wider area than a typical KFM, have an input voltage range of +/−1 kV, and have a spatial resolution of about 10 micrometers.

Our invention utilizes an optical leverage method for an EFD in combination with a large shield to detect the deflection of the cantilevered arm 12 for voltage measurement, and thus our EFD can be categorized as a kind of scanning probe microscope (SPM). Our invention is configured to detect small variations in the vibrations of the cantilevered arm 12 that are caused by the presence of a charge on the SUT 40, and the shield 210 may be configured to reduce the effects that light may have on certain types of SUTs 40—in particular, those SUTs 40 that have photosensitive materials (e.g. a photoreceptor which reacts to the presence of light).

Surface voltage on a photoreceptor naturally decays even if the photoreceptor is located in a dark place (a.k.a. dark decay). Our EFD may include features to compensate for the expected dark decay characteristics of the specific photoreceptor of the SUT 40 in order to obtain an accurate estimate of the surface voltage when the measurement is actually made. One way of compensating for dark decay is to normalize the data produced by our EFD using information known about the dark decay rate and the difference in time between when the voltage was applied and when it was measured. Such compensation may be accomplished using a computer that has been programmed to receive force-information from the force detector 200, determine how much time has lapsed since the charge was applied to the SUT 40, select a compensation value corresponding to the lapsed time, and apply that compensation value to the force-information derived from the force detector 200.

The shield 210 described herein may be used as a means by which the surface voltage measurement by an EFD may be improved because the shield 210 reduces or eliminates scattered and leaked laser light that would otherwise expose photosensitive materials of the SUT 40. Also as described above, such a shield 210 can be positioned and operatively configured so as to reduce the ability of electrostatic forces to act on the force detector 200 in areas other than the tip 16—e.g. the cantilevered arm 12 or that portion of the shaft 204 that is nearest to the arm 12. With such a system, an EFD according to our invention may be configured to detect latent images on a photoreceptor SUT 40, which is a significant improvement over prior art EFD systems.

At the risk of repeating some of the information above, we provide the following information.

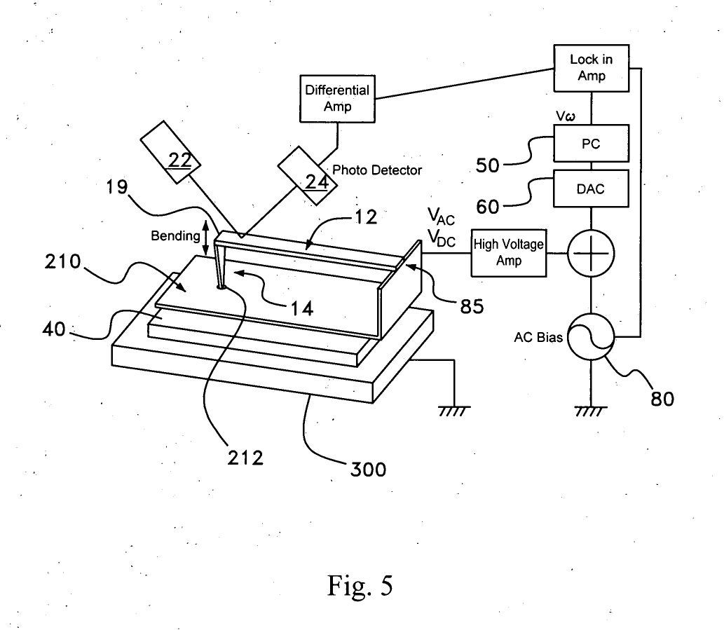

A schematic diagram of an embodiment of our EFD is shown in FIG. 5. In the EFD shown in FIG. 5, a DC bias voltage (V_{DC}) and an AC bias voltage (V_{AC} sin ωt) are applied simultaneously to the force detector 200 and shield 210. The tip 16, which is positioned between the shield 210 and the SUT 40 is caused to approach the SUT 40 (or vice versa), and the movement of the cantilevered arm 12 due to electrostatic attraction force caused by induction arising from the charge on the SUT 40 is detected. When the tip 16 is near a charge, the AC bias voltage applied to the detector 200 causes the arm 12 to vibrate, and the detected vibration includes the two cyclic components ω and 2ω. The electrostatic attraction force may be determined if we assume that the parallel plane model (see FIG. 2) accurately models our EFD and thus, we are able to obtain two different forces F_{ω} and F_{2ω} as shown in equations 2 and 3 (above), which are repeated below:

$$\begin{matrix}{F}_{ω} = \frac{{V}_{DC} - ρ {d}_{0} \text{/} ɛ}{{[ d - ( 1 - {ɛ}_{0} \text{/} ɛ ) {d}_{0} ]}^{2}} {ɛ}_{0} {SV}_{AC} sin ω t & ( 2 ) \\ {F}_{2 ω} = \frac{- 1}{{4 [ d - ( 1 - {ɛ}_{0} \text{/} ɛ ) {d}_{0} ]}^{2}} {ɛ}_{0} {SV}_{AC}^{2} cos 2 ω t & ( 3 )\end{matrix}$$

If a DC bias voltage is applied to the probe 14, and that DC bias voltage is equal to the surface voltage (ρd₀/ε) of the SUT 40, then from equation 2 we understand that F_{ω} is zero. Whenever the surface voltage measurement is conducted with the EFD, the bias voltage V_{DC} is controlled so as to bring F_{ω} equal to zero, and this may be done by controlling the feedback loop. This method allows for measuring the surface voltage of the SUT 40 without arcing between the tip 16 and the SUT 40. High spatial resolution measurement can be done with this method as well.

Surface Voltage Measurement on Photoreceptor with EFM.

Light Leakage Suppression Apparatus:

In operation of an embodiment of our EFD that employs an optical leverage system, laser light may be directed to a reflective surface on the cantilevered arm 12. Assuming a measurement duration of 100 sec, one embodiment of our invention may be configured to control the light leakage amount to less than 1.5 nW. In order to satisfy these conditions, that embodiment of our invention may incorporate one or more of three improvements: (1) a change in the shape of the cantilevered arm 12, (2) use of the improved shield 210, and (3) improvements of the procedures used to measure changes on the SUT 40. These three improvements are described below.

Change of Cantilever Shape.

To be a more efficient light shield, embodiments of the invention may have a cantilevered arm 12 that is wider than arms found in the prior art. However, if the width of the cantilevered arm 12 is increased, and nothing else changes, then the spring constant of the cantilevered arm 12 will increase. Since the spring constant impacts important elements of the system (such as resonant frequency and detecting sensitivity) it is desirable to minimize the change in spring constant, and this may be accomplished by increasing the length of the cantilevered arm 12. Table 1 shows information corresponding to a prior art arm 12 and an arm 12 according to the invention.

TABLE 1
Dimensions of new cantilever and detector

| | Cantilever | Cantilever | Resonant |
|---|---|---|---|
| | length | width | frequency |
| | L [μm] | B [μm] | [Hz] |
| Conventional | 800 | 350 | 3000 |
| cantilever | | | |
| New | 1800 | 700 | 1257 |
| cantilever | | | |

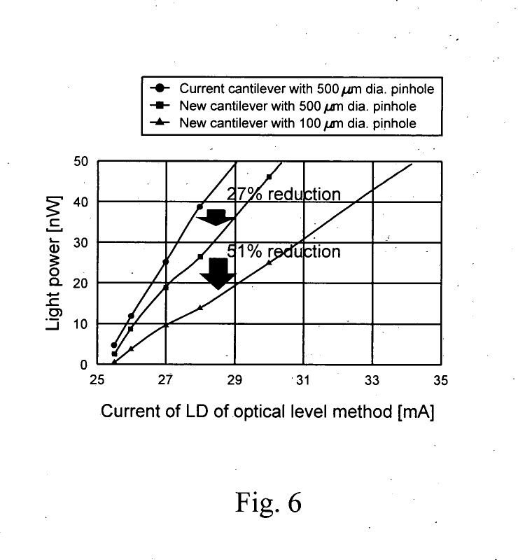

Table 1 is further described below in conjunction with FIG. 6

Confirmation of Light Shield Performance.

As mentioned, we changed the cantilevered arm's 12 dimensions to make it wider and longer than cantilevered arms 12 found in the prior art. By utilizing a wider and longer arm 12, light is prevented from reaching the SUT. Alternatively or in addition, our invention may deploy a larger shield 210, and having a pin hole 212 in the shield 210 in order to reduce the ability of light to reach the SUT 40. Such a shield 210 also reduces the unwanted electrostatic forces on the force detector 200 by limiting the electrostatic forces to that portion of the probe 14 that resides between the shield 210 and the SUT 40. In order to improve the ability of the shield 210 to prevent light from reaching the SUT 40, the pin hole 212 diameter should be carefully sized so as not to be larger than is needed to allow free movement of the probe tip 16.

FIG. 6 illustrates the benefits that may be achieved by using our invention. In FIG. 6 three plots are shown. The top-most plot identifies data obtained using an EFM having the characteristics of the conventional cantilever identified on Table 1. The middle plot and lower plot identify data obtained using an EFM having the characteristics of the new cantilever identified on Table 1. The data of the middle plot was obtained using a shield having a hole 212 having a diameter of 500 μm and the probe shaft 204 had a diameter of 50 μm. The data of the lower plot was obtained using a shield having a hole 212 diameter of 100 μm and the probe shaft 204 had a diameter of 50 μm. Note that a 27% reduction in unwanted light reaching the SUT 40 was achieved by using our shield with a hole 212, and a further reduction of 51% was achieved by narrowing the hole 212 to be close to the diameter of the probe shaft 204.

In one embodiment of the invention, we measured the relation between the current flow into the laser diode of the laser 22 versus light power of leaked laser light, and the relationship is shown in FIG. 6. From FIG. 6, one can see that the leaked light power was suppressed to less than 1.5 nW if the current flow to the laser diode of the laser 22 is controlled to less than 25 mA and a shield 210 according to the present invention is utilized. As such, a system according to our invention also may include a reduction in power to the laser 22 (relative to prior art systems), and/or the ability to adjust the power delivered to the laser 22. Alternatively, a laser 22 having a lower power than prior art systems may be employed.

Improvements on Measurement Routine for Photosensitive Materials.

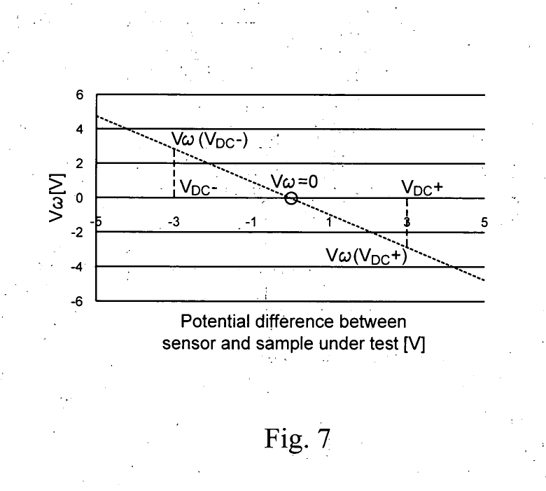

With reference to FIG. 7 and the description above, one embodiment of our EFD utilizes a voltage signal V_{ω}, which is obtained from a differential amplifier that is part of the detection circuit 30. The vibration sensed by the detection circuit 30, which is configured to employ equation 2 is introduced to the differential amplifier. Data for one embodiment of our invention is shown in FIG. 7. In FIG. 7 is shown the relation between V_{ω} and the voltage difference between the SUT 40 voltage and V_{DC}. It will be noticed from FIG. 7 as well as equation 2 that the relation between V_{ω} and that voltage difference can be regarded as a linear function.

Feedback control may be accomplished by applying to the probe 14 an initial DC voltage having a certain range (V_{DC-HIGH} to V_{DC-LOW}) in order to obtain a V_{DC} where V_{ω} becomes zero from V_{ω}(V_{DC-HIGH}) and V_{ω}(V_{DC-LOW}) while a measurement is underway. Therefore, prior to commencement of each charge measurement, an expected voltage range may be established. The target voltage and range are used to adjust the input range of the AD/DA converter, and also to bias the probe 14 so that the charge on the SUT 40 can be accurately measured as well as to prevent arcing between the tip 16 and the SUT 40.

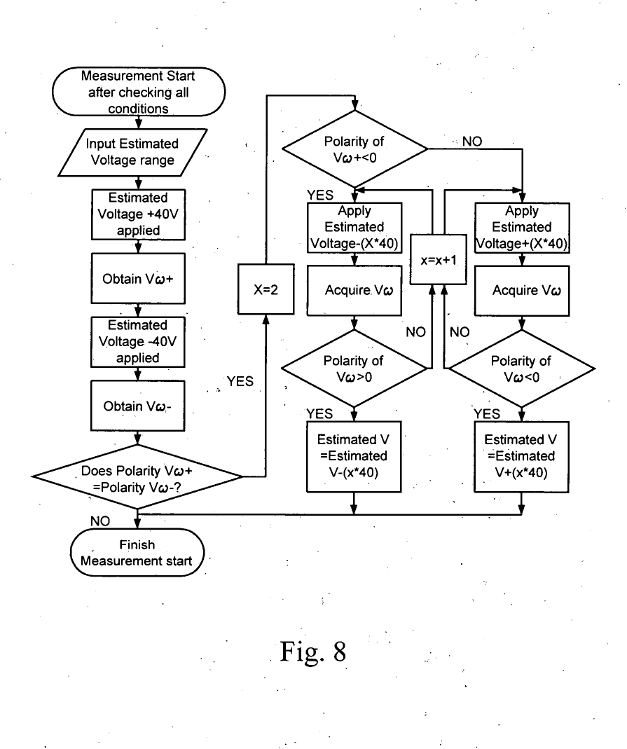

The flow chart of FIG. 8 illustrates a method of making an SUT 40 charge measurement and minimizing the experience needed to properly operate an EFM. By following the method of FIG. 8, the target voltage range expected to be measured by the force detector 200 can be adjusted quickly relative to what might be achieved without such a method. For purposes of this discussion, the “target voltage” is an expected voltage on the SUT 40. With reference to FIG. 8, an initial step may involve verifying whether the target voltage resides within an expected range. To do so, an estimated voltage is selected and a range is established, for example by adding a predetermined number to the estimated voltage and subtracting a predetermined number from the estimated voltage. To illustrate this step, if the estimated voltage is selected to be 0 volts, then the range might be found by adding and subtracting 40 Volts to arrive at a range that extends from −40 Volts to +40 Volts (referred as V_{DC-LOW} and V_{DC-HIGH}). Then V_{DC-LOW} may be applied to the probe and a charge measurement (V_{ω}(_{VDC-LOW}), which is sometimes referred to as V_{ω-}) is obtained. And, in another step, V_{DC-HIGH} may be applied to the probe and a charge measurement (V_{ω}(_{VDC-HIGH)}, which is sometimes referred to as V_{ω+}) is obtained. Next, the polarities of V_{ω-} and V_{ω+} are compared to determine whether those polarities are the same or different. If those polarities are different, then the range is properly positioned, and the charge on the SUT 40 at that location can be determined. However, if those polarities are not different, then the range is shifted up or down and a new pair of polarities is obtained and compared. This process is repeated until the polarities of V_{ω-} and V_{ω+} are different.

To determine whether to shift the range up or down, the polarities of V_{ω-} and V_{ω+} are examined, and if both polarities are less than zero, then the range is shifted down, but if both polarities are greater than zero, then the range is shifted up. In FIG. 8, the shifting is done by adding or subtracting the predetermined amount (e.g. 40 Volts) to the prior estimated voltage.

By executing such a method, arcing between the SUT 40 and the probe 14 may be avoided. For example, the probe tip 16 may be initially positioned at a distance that is far from the SUT 40, and then executing the method described above to determine a range of voltages that includes the charge. With that range having been selected, the probe tip 16 may then be moved closer to the SUT 40, but not so close that arcing is likely to occur, and the method is again executed using the previously selected range as a starting point, and modifying the range until the polarities differ. Once a new range has been selected, the probe tip 16 can again be moved closer to the SUT 40, but not so close that arcing is likely to occur, and the method is repeated again. This process can be repeated until the probe tip 16 is a desired distance from the SUT 40, at which point the charge on the SUT 40 is measured and provided to a user. It will now be recognized that a method according to the invention may be thought of as moving the probe tip 16 incrementally so as to approach the SUT 40 without risking the generation of an arc between the SUT 40 and probe tip 16.

Light Decay Measurement with EFM.

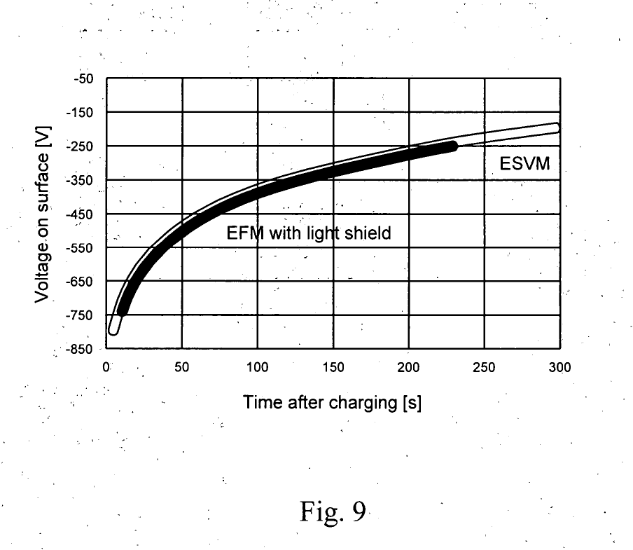

For a particular embodiment of the invention, we made measurements of a photoreceptor using an EFM having a light shield 210 according to our invention and our new measurement routine described above. For comparison purposes, we made similar surface 40 voltage measurements with a conventional electrostatic voltmeter (Trek Model 347). In order to secure the same measurement conditions, the relative humidity in the measurement area was set at 1.2% for both the EFM and the electrostatic voltmeter. The EFM included a shield 210 with a pin hole 212 having a diameter of 100 micrometers through which the probe 14 extended. At the location where the probe 14 extended through the hole 212, the probe's diameter was 50 μm. The current flow to the laser diode was set at 7 mA. FIG. 9 depicts the change in surface 40 voltage with time. The X-axis of FIG. 9 represents the time elapsed after charging the photoreceptor of the SUT 40. The data corresponding to the EFM, and the data corresponding to the electrostatic voltmeter are very similar, if not identical. These measurements were repeated three times each for the EFM and the electrostatic voltmeter, and the similarity was confirmed via these repetitions. Consequently, the test data plotted in FIG. 9 shows that (1) an EFM according to our invention can measure the surface voltage on a photoreceptor SUT 40 while preventing light from the laser 22 having a measurable influence on the SUT 40, and (2) our invention can result in the ability to measure the surface potential of the SUT 40 without the operator having a high level of expertise. Note that the data corresponding to the EFM (which uses laser light) tracks very closely with the data for the electrostatic voltmeter (which does not use light). Thus, even when the SUT 40 is photosensitive, our invention (which uses light) can be used to obtain data similar or equivalent to devices that do not use light.

Measurement of Latent Image on Photoreceptor.

We tried to measure a latent image on a photoreceptor SUT 40 using an EFD that is in keeping with our invention. For purposes of comparison, we used SUT's 40 having conventional organic photoreceptors with either high mobility or low mobility. A scorotron was used to apply charge on the SUT 40 photoreceptors. To the tungsten wire of the scorotron, we applied −4 kV, and −800 V to the grid. For the purpose of creating a latent image on the SUT 40 photoreceptors, a laser 22 having a beam diameter of 50 micrometers and a wavelength of 670 nm was employed. Upon creation of the latent image, a pulse generator was used to control the exposure time. Table 2 shows that the exposure energy density was controlled to be in the range of 1.7 to 28.5 mJ/m².

TABLE 2
Exposed time—energy density

| Exposure time | Energy | Energy density |
|---|---|---|
| 30 | 3.4 | 1.7 |
| 50 | 5.6 | 2.9 |
| 100 | 11.2 | 5.7 |
| 300 | 33.6 | 17.1 |
| 500 | 56.0 | 28.5 |

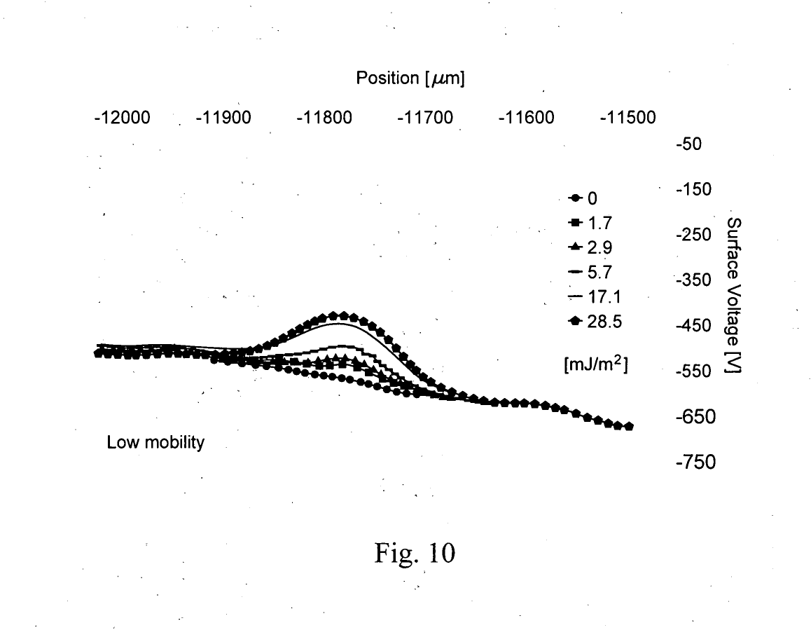

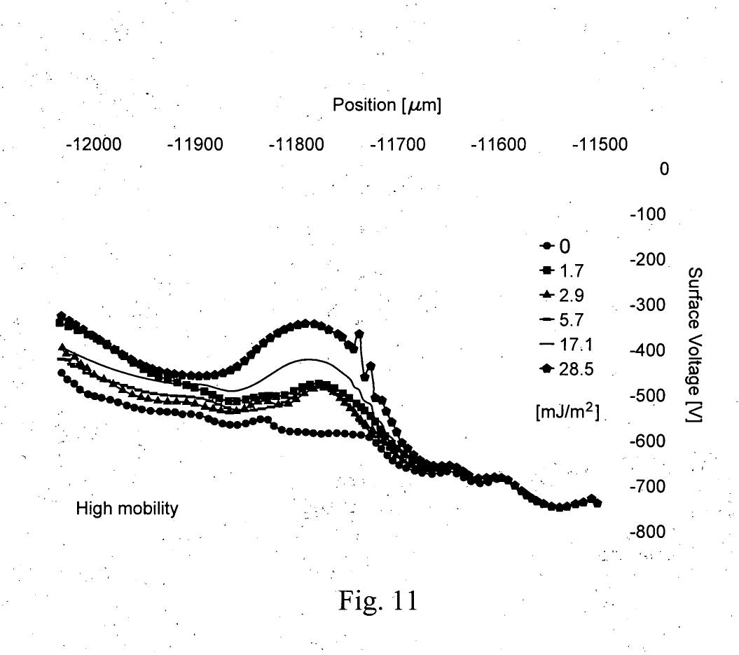

The test results are shown in FIG. 10 and FIG. 11. The inclined nature of those plots illustrates the effects of dark decay on photoreceptors. For each of FIG. 10 and FIG. 11, the scanning direction of the detector was from the right side to the left side of each graph. We were able to acknowledge the tendency that the voltage change happened significantly at the center of latent images in accordance with the increase of exposure energy density on both photoreceptors. As compared to the data corresponding to the low mobility photoreceptor, more data dispersions can be seen in the latter half of the data corresponding to the high mobility photoreceptor.

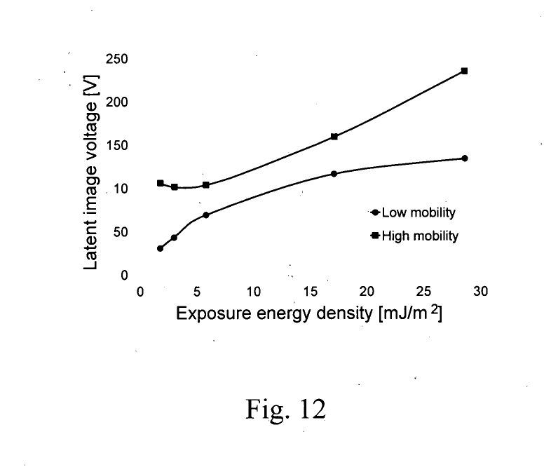

We have obtained the latent image voltage in accordance with several different exposure energy density levels. These data are shown in FIG. 12. As expected, FIG. 12 shows that compared to the photoreceptor with lower mobility, the latent image from the photoreceptor with higher mobility had higher voltage swings.

We measured the surface potential of an SUT 40 photoreceptor, as well as a latent image. Our EFD with a light shield 210 and measurement routine for the surface voltage measurement on an SUT 40 photoreceptor achieved superior results. Additionally, our data shows an ability to detect a latent image using our EFD in situations having different mobility, and we have confirmed that our EFD has the capability to characterize the photoreceptor's mobility difference.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

1. An electrostatic force detector (“EFD”) for measuring electrostatic force of a surface under test (“SUT”), the EFD comprising:
(a) a force detector having a cantilevered arm and a probe, the probe extending from the cantilevered arm at a location that is distal from a fulcrum of the cantilevered arm and oriented so that electrostatic force due to electrostatic charge on the SUT is induced at a tip of the probe;
(b) an optical system for transforming bending of the cantilevered arm due to electrostatic force induced at the tip into an electrical signal containing a frequency component of the electrostatic force induced at the tip;
(c) a voltage source for applying bias voltage to the force detector;
(d) a frequency detector for detecting the frequency component of the electrical signal so that a measurement of electrostatic charge on the SUT can be obtained; and
(e) a shield having a surface defining a hole through the shield, the hole being sized to allow movement of the probe relative to the shield, and the shield being positioned to inhibit electromagnetic energy from the SUT from reaching the cantilevered arm and to prevent light from reaching the SUT, wherein the shield is located between the cantilevered arm and the SUT, and a portion of the probe extends through the hole in the shield.

2. The EFD of claim 1, wherein the shield is located closer to the SUT than to the cantilevered arm.

3. The EFD of claim 1, wherein the shield is maintained at the same electrical potential as the force detector so that lines of electrostatic force are terminated at the shield.

4. The EFD of claim 1, wherein a length of the cantilevered arm is between 900 μm and 3600 μm.

5. The EFD of claim 1, wherein a width of the cantilevered arm is between 400 μm and 1400 μm.

6. The EFD of claim 5, wherein a width of the shield is equal to or greater than the width of the cantilevered arm.

7. The EFD of claim 1, wherein a width of the shield is equal to or greater than a width of the cantilevered arm.

8. (canceled)

9. (canceled)

10. (canceled)

11. (canceled)

12. (canceled)

13. (canceled)

14. (canceled)

15. (canceled)
